(19) United States
(12) Patent Application Publication
(10) Pub. No.: US 2009/0004363 A1
(43) Pub. Date: Jan. 1, 2009

(54) PLASMA ENHANCED CHEMICHAL VAPOR DEPOSITION APPARATUS AND METHOD

(76) Inventors: Marvin S. Keshner, Sonora, CA (US); Paul H. McCleland, Monmouth, OR (US)

Correspondence Address: WEISS & MOY PC, 4204 NORTH BROWN AVENUE, SCOTTSDALE, AZ, 85251, US

(21) Appl. No.: 12/206,040

(22) Filed: Sep. 8, 2008

Related U.S. Application Data
(63) Continuation of application No. PCT/US2004/030275, filed on Sep. 14, 2004.
Application No. PCT/US2004/030275 is a division of application No. 11/553,334, filed on Oct. 26, 2006.

(51) Int. Cl. C23C 16/52; C23C 16/513; C23C 16/30

(52) U.S. Cl. 427/8; 427/569; 427/578

(57) ABSTRACT

A substrate processing system includes a deposition chamber and a plurality of tubular electrodes positioned within the deposition chamber defining plasma regions adjacent thereto.

### CROSS REFERENCE TO RELATED APPLICATIONS

This application is a continuation of PCT US/2004/030275 filed Sep. 14, 2004 and a divisional application of copending U.S. patent application Ser. No. 11/553,334 filed Oct. 26, 2006, and to which priority is claimed.

### BACKGROUND

Plasma enhanced chemical vapor deposition (“PECVD”) systems may be used, for example, in semiconductor manufacturing processes to deposit thin films of silicon onto a substrate. Conventional PECVD systems include a deposition chamber with two or three electrodes that, when excited by a voltage, ionize the reactant gas between the electrodes to create a plasma. In many instances, the reactant gas is supplied directly into the high intensity plasma region through one of the electrodes, which is commonly referred to as a “showerhead” electrode.

Although PECVD has proven to be a useful process, the present inventors have determined that conventional PECVD processes are susceptible to improvement. More specifically, the present inventors have determined that the deposition rates of conventional PECVD processes must be kept relatively low in order to produce acceptable film quality and, given the fact that the cost of conventional PECVD systems is comparable to the cost of deposition systems such as sputtering systems that have higher deposition rates, the per unit area cost of films produced by conventional PECVD processes is relatively high. The present inventors have also determined that conventional PECVD processes consume reactant materials (e.g. silane) inefficiently because the concentration of the silane in the reactant gas (e.g. silane and hydrogen) is only marginally higher than the concentration of the reactant material in the exhaust. As such, the vast majority of the silane flows through the system and is not utilized by the deposition process, thereby being wasted. The present inventors have also determined that silicon particles can form in the plasma unless conventional PECVD processes are operated at low gas pressures, low reactant material concentrations, and low excitation power, all of which result in low deposition rates. The formation of silicon particles is problematic, thereby necessitating the low deposition rates, because the particles can damage the vacuum pumps that draw exhaust gasses from the deposition chamber and can also damage the devices being formed. The vacuum pumps must also be relatively large so that the slightly used gas within the deposition chamber can be rapidly withdrawn before the silane concentration becomes too low or the silane distribution becomes non-uniform. The present inventors have also determined that conventional PECVD processes require the reactant gas to flow through the length (or width) of the entire chamber before the reactant gas is exhausted. This results in a long dwell time for silane molecules within the chamber that exacerbates the formation of silicon particles and also increases the formation of higher order silanes (e.g. Si₂H₆). A significant concentration of higher order silanes results in very poor device quality. Therefore, the flow rates are kept high to exhaust the higher order silanes quickly and avoid their accumulation. As a result, most of the silane flows through the system and is exhausted rather than used efficiently in the reaction to deposit silicon. The present invention fulfills these needs and provides other related advantages.

### SUMMARY OF THE INVENTION

In accordance with one embodiment of a present invention, a substrate processing system is disclosed, comprising a deposition chamber; and a plurality of tubular electrodes positioned within the deposition chamber, defining plasma regions adjacent thereto, and having internal lumens and apertures that connect the internal lumens to the deposition chamber.

In accordance with another embodiment of the present invention, a substrate processing system is disclosed, comprising: a deposition chamber; first and second substrate carriers located within the deposition chamber; a plurality of spaced elongate electrodes positioned between the first and second substrate carriers; and a power supply operably connected to each of the electrodes and adapted to drive adjacent electrodes out of phase from one another.

In accordance with another embodiment of the present invention, a method of forming a film is disclosed, comprising the steps of: generating a plasma region having a relatively high intensity and a plasma region having a relatively low intensity; and introducing a reactant including film layer material into the relatively low intensity plasma region.

In accordance with another embodiment of the present invention, a substrate processing system is disclosed, comprising: means for generating a plasma region having a relatively high intensity and a plasma region having a relatively low intensity; and means for introducing a gas including film layer material into the relatively low intensity plasma region.

In accordance with another embodiment of the present invention, a substrate processing system is disclosed, comprising: a deposition chamber; at least one substrate carrier located within the deposition chamber and adapted to guide a substrate in a substrate travel direction; and a plurality of elongate rod electrodes spaced from one another in the substrate travel direction and defining respective longitudinal axes that extend in a direction that is at least transverse to the substrate travel direction.

In accordance with another embodiment of the present invention, a substrate processing system is disclosed, comprising: a deposition chamber defining an interior having a length and a height; first and second substrate carriers located within the deposition chamber adapted to position first and second substrates apart from one another by a distance that is no more than one-tenth of the height and no more than one-fifteenth of the length measured in a direction that is perpendicular to the length and the height; and an electrode assembly located between the first and second substrate carriers and adapted to create plasma between the first and second substrate carriers.

In accordance with another embodiment of the present invention, a method of forming a film on a substrate is disclosed, comprising the steps of: generating a plasma within a deposition chamber; introducing a reactant including film layer material into the plasma at a reactant input rate; depositing the film layer material onto the substrate; evacuating exhaust from the from the deposition chamber; measuring the amount of film layer material in the exhaust; and adjusting the reactant input rate in response to the measured amount of film layer material in the exhaust.

Other features and advantages of the present invention will become apparent from the following more detailed description, taken in conjunction with the accompanying drawings which illustrate, by way of example, the principles of the invention.

### BRIEF DESCRIPTION OF THE DRAWINGS

Detailed description of embodiments of the inventions will be made with reference to the accompanying drawings.

FIG. 1 is a block diagram of a PECVD apparatus in accordance with an embodiment of a present invention.

FIG. 2 is a perspective, cutaway view of a deposition chamber in accordance with an embodiment of a present invention.

FIG. 3 is a section view taken along line 3-3 in FIG. 2.

FIG. 4 is a side view of rod electrodes in accordance with an embodiment of a present invention.

### DETAILED DESCRIPTION OF THE ILLUSTRATED EMBODIMENTS

The following is a detailed description of the best presently known modes of carrying out the inventions. This description is not to be taken in a limiting sense, but is made merely for the purpose of illustrating the general principles of the inventions. It should also be noted that detailed discussions of the various aspects of PECVD systems that are not pertinent to the present inventions have been omitted for the sake of simplicity. Additionally, although the inventions are described in the context of the formation of thin films of silicon (Si) from silane (SiH₄), they are not limited to any particular types of films or input reactant material. By way of example, but not limitation, the inventions also have application in the deposition of silicon carbide (SIC), amorphous silicon Si(H), micro-crystalline silicon Si(H), silicon germanium (SiGe) and other semiconductor materials, all with hydrogen (H) incorporated. Doped semiconductor materials can also be fabricated. The dopant is most easily input to the system as a gas, but could also be introduced by including a solid piece of doped silicon in the plasma region. Gas sources for doping materials include, for example, tri-methyl borane (B(CH₃)₃) and phosphine (PH₃).

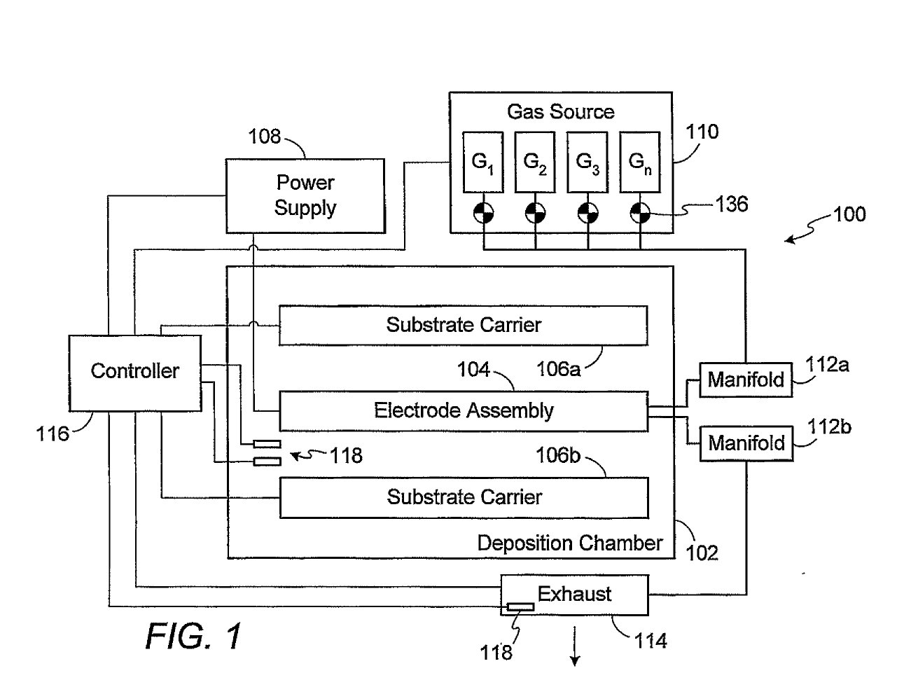

As illustrated for example in FIG. 1, a PECVD system 100 in accordance with one embodiment of a present invention includes a deposition chamber 102 with an electrode assembly 104 between a pair of substrate carriers 106a and 106b. The substrate carriers 106a and 106b position substrates on opposite sides of the electrode assembly 104. The electrode assembly 104 in the exemplary implementation performs a number of functions. The electrode assembly 104 creates one or more high intensity plasma regions between the substrate carriers 106a and 106b when excited by a voltage, e.g. radio frequency (RF) or direct current (DC), provided by a power supply 108. The electrode assembly 104 is also used to deliver reactant gas to the deposition chamber 102 and is connected to a reactant gas source 110 by way of a manifold 112a. During the deposition process, plasma is created in the area between substrates that are carried by the substrate carriers 106a and 106b and material from the reactant gas (e.g. silicon from silane) is deposited from the plasma onto both of the substrates simultaneously to form films (e.g. silicon films) on both of the substrates. In addition, the electrode assembly 104 is used to evacuate exhaust from the deposition chamber 102 and, to that end, is connected to an exhaust device 114, such as vacuum pump, by way of the manifold 112b. Operation of the PECVD system 100 is monitored and controlled by a controller 116, based at least in part on data from sensors 118.

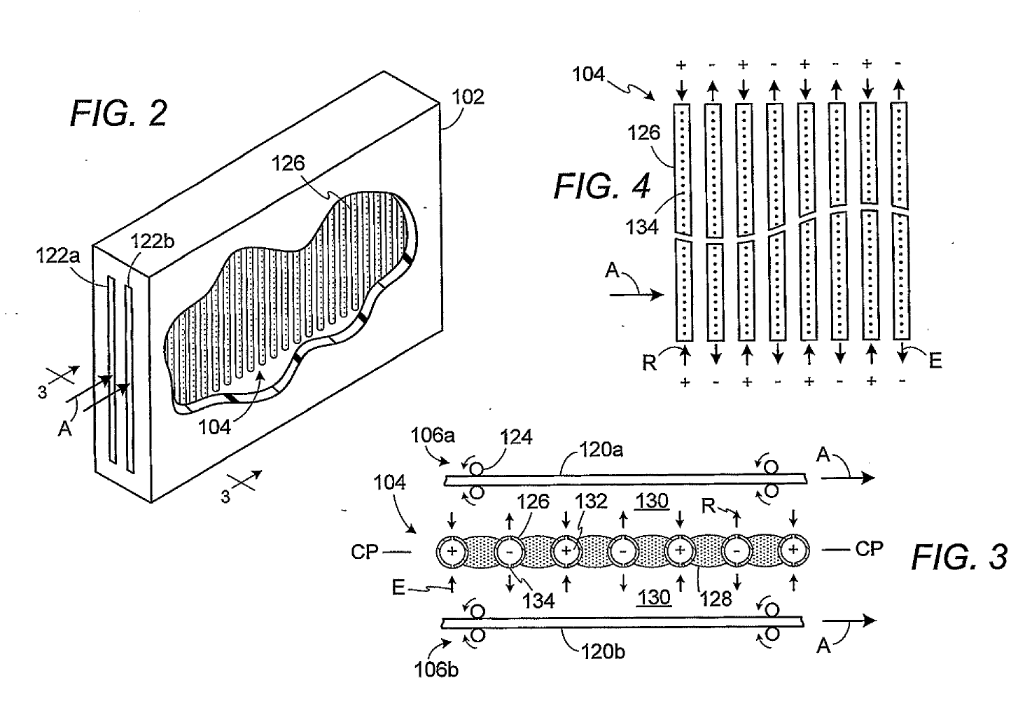

Turning to FIGS. 2-4, the substrates 120a and 120b enter the exemplary deposition chamber 102 by way of inlets 122a and 122b and travel in the direction indicated by arrows A. Similar outlets (not shown) are provided at the opposite end of the deposition chamber 102. The substrates 120a and 120b will be in the form of individual sheets of substrate material that are each fed into the deposition chamber 102. The substrates may also be a continuous web of substrate material that is pulled from a supply roll to a take-up roll. Suitable substrate materials include, but are not limited to, soda-lime glass, polyimide, and stainless steel. Whether in individual sheet or roll form, the substrate carriers 106a and 106b position the substrates 120a and 120b parallel to each other on opposite sides of the deposition chamber 102 and on opposite sides of the electrode assembly 104. The substrate carriers 106a and 106b also include a plurality of rollers units 124 and the edges of the substrates 120a and 120b pass between the rollers in the associated roller units. The rollers in the roller units 124 may be free spinning rollers, which merely guide the substrates 120a and 120b through the deposition chamber 102 and ensure that they are properly positioned within the chamber. Alternatively, the rollers units 124 may include driven rollers that drive the substrates 120a and 120b through the deposition chamber 102, in addition to insuring that they are properly positioned. Other suitable substrate carriers include conveyor systems and chain drives. Alternatively, the substrates could be loaded into the chamber by a robot arm, held in place by sliding or roller guides and then removed from the chamber by the robot arm after the deposition is complete. Still another alternative is to employ rollers that engage the top and bottom edges of the substrates 120a and 120b and rotate about axes that are perpendicular to the direction indicated by arrows A.

The interior of the deposition chamber 102 in the exemplary embodiment is relatively narrow. More specifically, the distance between the substrates 120a and 120b is substantially less than the length of the chamber (measured in the direction of arrows A) and the height of the chamber (measured in the direction perpendicular to arrows A). For example, the distance between substrates 120a and 120b may be one-tenth or less of the length and height dimensions. The substrates 120a and 120b will also preferably extend from end to end in the length dimension of the deposition chamber 102 and from top to bottom in the height dimension. As a result, the substrates 120a and 120b will be between the electrode assembly 104 (and the plasma created thereby) and the large interior surfaces of the chamber and will cover the vast majority of the interior surface of the deposition chamber 102.

The deposition chamber 102 is not limited to any particular size. Nevertheless, in one exemplary implementation of the deposition chamber 102 that is suitable for commercial applications and is oriented in the manner illustrated in FIG. 2, the interior of the deposition chamber 102 is about 100 cm in length (measured in the direction of arrows A) and about 60 cm in height (measured in the direction perpendicular to arrows A). There is also about 7 cm between the substrates 120a and 120b and 3.5 cm between the central plane CP of the deposition chamber interior (FIG. 3) and each of the substrates 120a and 120b. Additionally, the substrate carriers 106a and 106b are positioned and arranged such that the substrates 120a and 120b will lie in vertically extending planes. Such orientation reduces the likelihood that particulates will fall onto the substrates.

There are a number of advantages associated with deposition chambers that are configured in this manner. For example, the relatively small spacing between the substrates 120a and 120b, as compared to the relatively large dimension in the direction of substrate travel and the dimension perpendicular to substrate travel increases the percentage of the plasma generated silicon that is deposited onto the substrates and decreases the amount that is deposited onto the chamber walls, as compared to conventional deposition chambers. As a result, the reactant materials are consumed more efficiently. The downtime and expense associated with deposition chamber cleaning and maintenance is also reduced. The close spacing between the electrode assembly 104 and the substrates 120a and 120b also facilitates rapid diffusion in the smallest dimension to be the dominant process for transporting atomic hydrogen created at the center of the deposition chamber 102 to the substrates, where the atomic hydrogen can react with silane to create the pre-cursors that result in the deposition of good quality semiconductor material onto the substrates. The configuration of the deposition chamber 102 also allows rapid diffusion to equalize the concentrations of all species throughout the plasma, including the rapid diffusion of the input reactant gas, to obtain a uniform concentration.

The exemplary electrode assembly 104 illustrated in FIGS. 2-4 includes a plurality of spaced rod electrodes 126 arranged such that their respective longitudinal axes are co-planar, perpendicular to the direction of substrate travel (indicated by arrows A), and equidistant from the substrate carriers 106a and 106b (as well as substrates 120a and 120b). The rod electrodes 126 also extend from one end of the deposition chamber 102 to the other (top to bottom in the orientation illustrated in FIG. 2). The exemplary rod electrodes 126 are cylindrical in shape and are relatively close together. The spacing between adjacent rod electrodes 126 in the illustrated embodiment is about equal to the diameter of the rod electrodes (i.e. two times the diameter measured from longitudinal axis to longitudinal axis).

With respect to plasma formation, the electrode assembly 104 may be used to create high intensity plasma between the substrate carriers 106a and 106b (as well as substrates 120a and 120b). The high intensity plasma is created when the rod electrodes 126 are energized by power such as, for example, RF or DC power from the power supply 108. The energy is supplied in alternating phases from one rod electrode 126 to the next adjacent rod electrode, as is represented by the alternating series of “+” and “−” signs in FIGS. 3 and 4. The application of power in this manner creates regions of high intensity electric field between adjacent rod electrodes 126 and, accordingly, regions of intense plasma 128 between adjacent rod electrodes. Low intensity electric fields and low intensity plasma regions 130 are created near the substrates 120a and 120b. More specifically, in an exemplary implementation where adjacent rod electrodes 126 are spaced from one another by one rod diameter (i.e. two diameters from longitudinal axis to longitudinal axis) and the substrates spaced from the central plane CP by three and one-half rod electrode diameters, the intensity of the electric fields between the rod electrodes will be significantly greater than ten times the intensity of the electric field near the substrates 120a and 120b.

It should be noted that the rod electrodes 126 may, alternatively, be driven in phase with each other. Here, the substrates 120a and 120b are held at ground potential or at ground with a small DC bias. This will create a relatively uniform electric field and plasma in each of the two areas between the central plane CP and the substrates 120a and 120b.

Since the rod electrodes 160 present a load having a capacitive reactance (due to the length of the rod electrode being less than one-quarter wavelength of the excitation frequency), the RF energy is coupled to the rod electrode in parallel with an inductive reactance so as to create a predominantly resonant circuit. In the embodiment of FIGS. 3 and 4, each rod electrode 126 is preferably electrically driven at both longitudinal ends in order to reduce amplitude variations of the excitation signal along the length of the electrode. This minimizes the effects of standing waves at high RF frequencies and provides a relatively even plasma intensity along the length of each electrode. Additionally, electrical contacts (not shown) may be provided to connect substrates 120a and 120b to the system ground, or to bias the substrates positive or negative with respect to the system ground, to control the plasma properties and the amount of electron/ion bombardment at the surface of the substrates. Magnetic fields may also be used to control plasma properties, i.e. confine the plasma and direct the movement of ions and electrons within the plasma.

With respect to materials, the rod electrodes 126 illustrated in FIGS. 2-4 may be formed from a variety of materials that are relatively high in thermal and electrical conductivity to achieve a uniform electrical field and uniform temperature along the length of the rod. Material that is inert in a hydrogen plasma, such as titanium or stainless steel, may be used. Alternatively, the rod electrodes 126 may be formed from a material, such as titanium or doped silicon that will be very, very slowly etched by the hydrogen plasma and deposited in minute quantities along with the silicon. This technique may be employed to introduce catalyst material such as titanium (Ti) that improves the growth rate or quality of the silicon and/or to introduce dopants such as boron (B) or phosphorous (P) without the need for toxic input gasses like phosphine (PH₃).

Turning to size and shape, the rod electrodes 126 in one implementation that is suitable for commercial applications are cylindrical in shape, are about 1.2 cm in diameter and about 60 cm in length. The rod electrodes 126 are positioned parallel to one another about every 2 cm (i.e. 2 cm between the longitudinal axes of adjacent rod electrodes) in the direction of substrate travel and in the central plane CP of the deposition chamber interior. Thus, in the illustrated embodiment, the central plane CP is also the electrode plane. So configured and arranged, there will be forty-six (46) of the rod electrodes 126 in a 100 cm long deposition chamber that has small electrode-free areas near the inlets and outlets. In another exemplary implementation, smaller rod electrodes that are about 0.6 cm in diameter and about 60 cm in length are positioned parallel to one another about every 1 cm (i.e. 1 cm between the longitudinal axes of adjacent rod electrodes) in the direction of substrate travel and in the central plane CP of the deposition chamber interior. So configured and arranged, there will be ninety-two (92) of the smaller rod electrodes 126 in a 100 cm long deposition chamber that has small electrode-free areas near the inlets and outlets. It should also be noted that, for both rod electrode 126 sizes, the spacing between adjacent rod electrodes is less than one twenty-fifth ( 1/25) of the length and the height of the interior of the deposition chamber 102 and relatively short as compared to the distance over which silicon particles and higher order silanes form.

The rod electrodes 126 are not, however, limited to these configurations and arrangements. For example, the rod electrodes may be other than circular in cross-sectional shape, as are the exemplary cylindrical rod electrodes 126. There may also be instances where the spacing between the rod electrodes 126 will vary, where some or all of the rod electrodes are slightly offset from the central plane CP and/or where some of the rod electrodes are not parallel to others. The cross-sectional size of the rod electrodes (e.g. the diameter where the rod electrodes are cylindrical) may also be varied from electrode to electrode to suit, particular applications.

There are a number of advantages associated with the present electrode assembly 104. For example, the arrangement of the plurality of closely spaced rod electrodes 126 allows higher RF frequencies to be used to excite the plasma in the present PECVD system 100, as compared to the frequencies that can be used in conventional PECVD systems, when the systems are of commercial production size (i.e. where the substrates are relatively long and at least 0.5 m wide). The series of parallel rod electrodes 126, with alternating phases of applied RF power, forms a series of well characterized electronic transmission lines capable of supporting high frequency RF excitation in the range of 27-81 MHz. It has been shown in laboratory experiments that RF power in the 27-81 MHz excitation frequency range can provide higher deposition rates (i.e. about 0.5 nm/sec.) and better material quality than the conventional excitation frequency of 13.5 MHz. Conventional electrode designs are not conducive to these higher frequencies in commercial production sized systems because they create poorly controlled standing waves, which results in non-uniform plasma intensity and non-uniform deposition rates. Conversely, the present electrode assembly 104 produces well controlled standing waves and only minor variations in plasma intensity when excited to a frequency of 80 MHz over relatively long substrates that are at least 0.5 m wide.

Other advantages are associated with the creation of high intensity plasma regions 128 along the central plane CP (FIG. 3) of the deposition chamber 102 and low intensity plasma regions 130 near the substrates 120a and 120b. For example, the high intensity plasma regions 128 generate abundant atomic hydrogen, which is known to encourage the formation of silicon with good semiconducting properties, and the distance from the central plane CP of the deposition chamber 102 to the substrates 120a and 120b is relatively short as compared to the diffusion length for atomic hydrogen. Atomic hydrogen generated in the central plane CP will diffuse easily to the substrates and unlike experimental systems that have been reported in PECVD-related literature, does not have to flow through a tube or other apparatus through which much of the atomic hydrogen would react and be lost. The high intensity plasma regions 128 in the central plane CP between the rod electrodes 126 also generate intense UV photons that can easily flow to the substrates 120a and 120b. Unlike other experimental systems that have been reported in PECVD-related literature, the UV photons can flow to substrate without passing from outside the deposition chamber through a window or other apparatus that decreases the photon intensity and creates a significant maintenance issue. The creation of low intensity plasma regions 130 near the substrates 120a and 120b reduces the electron/ion bombardment of the substrates and potential damage to the deposited silicon by electrons and/or ions.

It should also be noted that a series of rod electrodes that are arranged in the manner described above does not create a uniform electric field and plasma in the substrate travel direction indicated by arrows A and, instead, will create an electric field and plasma that varies periodically in the travel direction from the area closet to a rod electrode to the midpoint between two rod electrodes. The deposition rate and semiconducting properties of the deposited material could, therefore, vary periodically in the travel direction. The illustrated embodiment eliminates this periodic variation in electric field and plasma intensity in a variety of ways. Periodic variations are reduced to a large extent by insuring that the distance between adjacent rod electrodes 126, as well as the distance between the rod electrodes and the substrates 120a and 120b, is within a diffusion length. For example, in the exemplary embodiments, the spacing between adjacent rod electrodes 126, is less than half of the distance from the central plane CP to the substrates. In fact, the spacing between adjacent rod electrodes 126 and from the rod electrodes to the substrates 120a and 120b should be minimized so that rapid diffusion can further reduce variations in the deposition rate. Finally, if necessary, the substrates 120a and 120b can be moved relatively rapidly in the non-uniform direction (i.e. the direction indicated by arrows A) to average out any small, remaining variations in the deposition rate.

The electrode assembly 104 may, in some implementations of the present inventions, also be used during the deposition process to deliver reactant materials to the deposition chamber 102 and to evacuate exhaust from the deposition chamber. To that end, and referring to FIGS. 3 and 4, the rod electrodes 126 include interior lumens 132 that are connected to the manifold 112a (or 112b) and apertures 134 that connect the interior lumens to the interior of the deposition chamber 102. Each rod electrode 126 includes two sets of apertures 134, one set that faces the substrate 120a and another set that faces the substrate 120b. The interior lumens 126 in the illustrated embodiment are connected to the manifolds 112a and 112b such that, in the direction of substrate travel (i.e. the direction indicated by arrows A) the rod electrodes 126 alternate from one rod electrode to the next between delivering reactant materials and evacuating exhaust. The reactants are represented by arrows R in FIGS. 3 and 4, while the exhaust is represented by arrows E. More specifically, the manifold 112a connects the lumens 132 of the rod electrodes 126 that are delivering reactant material to the reactant gas source 110 and the manifold 112b connects the lumens of the rod electrodes that are evacuating exhaust to the exhaust device 114. The manifolds 112a and 112b are also connected to both longitudinal ends of each of the associated rod electrodes 126. As such, reactant materials enter both longitudinal ends of each of the rod electrodes 126 that are delivering reactant materials, and the exhaust exits both longitudinal ends of each of the rod electrodes that are evacuating exhaust.

The exemplary lumens 132 in the illustrated embodiment are slightly smaller than the rod electrodes 126. For example, the lumen 132 would be about 1.0 cm in diameter in a cylindrical rod electrode 126 that is itself 1.2 cm in diameter, and about 0.5 cm in diameter in a cylindrical rod electrode that is itself 0.6 cm in diameter. The apertures 134, which are about 350 μm in diameter in the larger rod electrodes 126 and about 200 μm in diameter in the smaller rod electrodes, are positioned about every 0.5 cm along the length of the rod electrodes 126. However, for both the rod electrodes 126 delivering reactant materials and the rod electrodes evacuating exhaust, there is preferably a slight variation in aperture spacing from the longitudinal ends of the rod electrodes 126 to the centers in order to compensate for the pressure drop that occurs between the longitudinal ends, which are connected to the manifold 112a, and the center. More specifically, for 0.6 cm diameter rod electrodes 126 with 200 um apertures 134, there is about 5% less spacing at the center (i.e. about 0.475 cm spacing) and about 5% more spacing at the longitudinal ends (i.e. about 0.525 cm spacing) and the change occurs linearly. This results in a uniform flow rate through the apertures 134 in the rod electrodes 126 from one longitudinal end of the rod electrodes 126 to the other. The apertures 134 may also be aligned with one another from one rod electrode 126 to the next, or staggered, as applications require.

As discussed above with reference to FIGS. 3 and 4, supplying energy in alternating phases from one rod electrode 126 to the next adjacent rod electrode (as represented by the “+” and “−” signs) creates high intensity plasma regions 128 and low intensity plasma regions 130. The apertures 134 are positioned so that they do not face the high intensity plasma regions 128 and, instead, face the low intensity plasma regions 130. In the exemplary implementation, the apertures 134 face in directions that are perpendicular to the central plane CP and are positioned on the portions of the rod electrodes 126 that are closest to the substrates 120a and 120b. The angle of the apertures 134 relative to the central plane CP may, however, be adjusted as applications require. For example, the angle may be up to forty-five (45) degrees from perpendicular. Because the reactant material, i.e. silane in the exemplary implementation, is introduced into the low intensity plasma regions 130, the silane rapidly diffuses and dilutes itself into the hydrogen atmosphere inside the chamber before encountering regions of intense plasma 128. This reduces the formation of higher order silanes and/or silicon particles within the plasma.

The reactant gas source 110 may be used to fill the deposition chamber 102 with hydrogen, or a mixture of hydrogen and argon (Ar), at the desired pressure (e.g. 300 mTorr) prior to the excitation of the rod electrodes 126 and the introduction of the silane or other reactant material. The rod electrodes 126 are then excited to initiate the plasma. During the actual deposition process, the reactant gas source 110 supplies pure or highly concentrated silane (rather than the dilute 5-10% silane in hydrogen associated with conventional devices) to the rod electrodes 126 that are supplying reactants by way of the manifold 112a. The apertures 134 direct the pure silane into the low intensity plasma regions 130 and the silane diffuses rapidly (i.e. within a few milliseconds) into the hydrogen already in the deposition chamber 102 to achieve an approximately 7% concentration of silane in hydrogen. The diffusion occurs before the silane reaches the high intensity plasma regions 128 where the silane is consumed by the decomposition into silicon and hydrogen (SiH₄→Si+2H₂). The rapid diffusion and dilution into the hydrogen atmosphere with the deposition chamber 102 prior to encountering high intensity plasma regions 128, as well as the relatively short rod electrode to adjacent rod electrode distance that the silane travels and correspondingly short residence time within the deposition chamber, also reduces the formation of higher order silanes (Si₂H₆, Si₃H₈, etc.) and/or silicon particles within the plasma. The silicon is deposited onto the substrates 120a and 120b, while the hydrogen and a very small amount of unused silane is removed by the apertures 134 in the other rod electrodes 126 and the exhaust device 114.

The input flow rate of the pure silane needs to be only slightly greater than the rate at which the silane is consumed because only a small amount of the silane is wasted. More specifically, when the gas in the deposition chamber reaches the apertures 134 in the rod electrodes 126 that are being used to evacuate exhaust from the deposition chamber 102, the gas is about 6% silane and 94% hydrogen. Additionally, because the deposition reaction is SiH₄→Si+2H₂, the exhaust gas flow rate should be roughly twice the input gas flow rate in order to maintain a constant pressure in the deposition chamber 102. By calculation, for a given reaction rate (n), the input gas flow rate=1.128 n SiH₄ and the exhaust gas flow rate=2.128 n (94% H₂+6% SiH₄). All of the hydrogen generated in the deposition reaction is removed by the exhaust, as is about 13% of the input silane. Hence, by calculation, 87% of the silane is used in the deposition process. Conventional PECVD systems, on the other hand, convert only about 15-20% of the silane into silicon and hydrogen and the remainder is wasted. Of course, in conventional PECVD systems and the present PECVD system 100, some of the silicon is deposited onto the walls of the deposition chamber. This brings conventional PECVD systems down to about 10-15% utilization efficiency, i.e. about 10-15% of the silicon input as silane gas is actually deposited onto substrates. As noted above, the geometry of the present deposition chamber 102 reduces the percentage of silicon that is deposited onto the walls of the deposition chamber and, accordingly, the overall utilization efficiency of the present PECVD system 100 is about 70%.

Another advantage associated with the supply of pure silane through some of the rod electrodes 126 and the evacuation of exhaust through others is that it facilitates much lower gas flow rates than conventional PECVD systems. For a given reaction rate (n), the input flow rate for conventional PECVD systems (7% silane in hydrogen) is 100n, the exhaust flow rate (6% silane in hydrogen) is 100n and, accordingly, the net consumption of silane is (7%−6%)×100n. In the present system, on the other hand, the input flow rate is 1.128n (100% silane), the exhaust flow rate is 2.128n (6% silane in hydrogen) and, accordingly, the net consumption of silane is (1.128n×100%)−(2.128n×6%). In other words, the input flow rate of the present PECVD system is almost 100 times less than conventional PECVD systems and the output flow rate is almost 50 times less. The lower flow rates allow for a much lower capacity exhaust device 114 (e.g. vacuum pump) to be used to evacuate the reaction products from the deposition chamber 102 and maintain a constant chamber pressure. The very short travel distance from a rod electrode 126 that is supplying reactant to a rod electrode that is evacuating exhaust (e.g. substantially less than one-twentieth ( 1/20) of the length and/or height of the deposition chamber 102 in the illustrated embodiment) ensures that the dwell time for silane in the reaction chamber 102 is short even though the flow rates are low. The short dwell time minimizes the formation of high order silanes and/or silicon particles.

As noted above, in an alternative implementation, the rod electrodes 126 are driven in phase with each other, and the substrates 120a and 120b held at ground potential (or at ground with a small DC bias), to create a relatively uniform electric field and plasma in each of the two areas between the central plane CP and the substrates. Here, the rod electrodes 126 may be rotated ninety (90) degrees from the orientation illustrated in FIG. 3 so that the apertures 134 are facing adjacent rod electrodes and reactant is supplied to, and exhaust is evacuated from, the region where the electrical field is minimized. This implementation of the inventions also benefits from the very short travel distance from a rod electrode 126 that is supplying reactant to a rod electrode that is evacuating exhaust in that the dwell time for silane in the reaction chamber 102 is short, even though the flow rates are low, and the short dwell time minimizes the formation of high order silanes and/or silicon particles.

The reactant gas source 110, which may be used to supply the deposition chamber 102 with hydrogen (or hydrogen and argon) prior the initiation of the deposition process and pure silane during the deposition process, includes a plurality of storage containers G₁-G_{N}. Other gasses that may be stored include argon, hydrogen, silane, methane, germane, and silane with dopant gasses such as tri-methyl borane or phosphine. The gasses may be stored under pressure and, to that end, the reactant gas source 110 includes a plurality of valves 136 that control the flow rate of the gasses from the storage containers G₁-G_{N}. It should also be noted that the present inventions are not limited to gaseous reactant material. Sources of liquid and/or solid reactants may also be provided if required by particular processes.

The controller 116 may be used to control a variety of aspects of the deposition process. For example, the rate at which pure silane is supplied to the deposition chamber 102 and the rate at which exhaust is evacuated from the deposition chamber may be controlled based upon data from the sensors 118. As noted above, the silane input rate should be slightly greater than the rate at which the silane is consumed (i.e. the deposition rate) because only a small amount of the silane is wasted. Thus, for a particular deposition rate and power level applied to the rod electrodes 126 by the power supply 108 (or “plasma power”), the input flow rate may be adjusted by feedback from the sensors 118 to achieve the desired concentration of silane in the exhaust gas. For an operating point in which the deposition rate is limited by the plasma power, the exhaust gas concentration of silane will typically be about 5-6%. Alternatively, for operating points in which the deposition rate is limited by silane depletion, the input flow rate of the silane is adjusted to be equal to the rate consumed in the deposition and the concentration of silane in the exhaust gas approaches zero. The exhaust rate is also controlled by feedback to maintain the pressure in the deposition chamber 102 at the desired pressure (e.g. about 300 mtorr). The temperature of the substrates 120a and 120b and the frequency and power level of the plasma excitation will also typically be controlled to achieve the desired quality of silicon at the desired deposition rate. Accordingly, the sensors 118 may include a gas concentration sensor associated with the exhaust device 114, a pressure sensor within the deposition chamber 102, and a temperature sensor associated with the substrates 120a and 120b. A sensor that detects the presence of a plasma to verify correct operation may also be provided.

Controlling the PECVD process in the manner described above allows the present PECVD system to perform continuous deposition processes at a stable, steady state with stable temperature, gas flow, gas concentrations, deposition rates, etc. The controller 116 can use feedback from the sensors 118 to adjust the parameters of the stable, steady state and achieve the desired material properties. The combination of steady state operation and parameter adjustment, based on sensors within the system as the deposition process proceeds, together with rapid diffusion to reduce any non-uniformity allows the manufacture of the present system to be much less precise in mechanical tolerances, and less uniform in gas flow. As a result, the present system can be manufactured much less expensively than conventional “batch mode” systems which deposit material with comparable uniformity and semiconducting properties.

The present PECVD system 100 may be used to produce a variety of material layers. By way of example, but not limitation, the PECVD system 100 may be used to form high quality amorphous or nano-crystalline silicon semiconductor layers on very large substrates (e.g. 1 m×0.5 m) that may be utilized in silicon photovoltaic cells and other large area, low cost devices.

Although the present inventions have been described in terms of the embodiments above, numerous modifications and/or additions to the above-described embodiments would be readily apparent to one skilled in the art. It is intended that the scope of the present inventions extend to all such modifications and/or additions.

We claim:

1. A method of forming a film layer on at least one substrate inside a deposition chambers comprising the steps of:
generating at least one plasma region having a relatively high intensity between a plurality of rod electrodes and away from at least one substrate and at least one plasma region having a relatively low intensity adjacent to the at least one substrate by driving adjacent rod electrodes out of phase from one another;
introducing a reactant including film layer material into the at least one region of relatively low intensity plasma;
depositing the film layer material onto the at least one substrate.

2. The method as claimed in claim 1, wherein RF power is supplied to each end of the adjacent rod electrodes.

3. The method as claimed in claim 1, wherein the adjacent rod electrodes have a parallel inductor attached to each longitudinal end.

4. The method as claimed in claim 1, wherein RF power is supplied in the 27-81 MHz excitation frequency range to drive the adjacent rod electrodes out of phase from one another.

5. The method as claimed in claim 1, wherein the step of introducing a reactant comprises introducing the reactant including film layer material into the at least one region of relatively low intensity plasma region through at least one of the plurality of rod electrodes.

6. The method as claimed in claim 5, wherein the plurality of rod electrodes have internal lumens and apertures that connect the internal lumens to the deposition chamber, wherein the apertures are oriented toward the at least one substrate and away from the plurality of rod electrodes.

7. The method as claimed in claim 1, wherein the plurality of rod electrodes define an electrode plane and the step of introducing a reactant comprises introducing a reactant including film layer material into the at least one relatively low intensity plasma region through at least one rod electrode and in a direction that is substantially perpendicular to the electrode plane.

8. The method as claimed in claim 1, wherein the step of introducing a reactant comprises introducing a substantially pure reactant including film layer material into the at least one relatively low intensity plasma region.

9. The method as claimed in claim 7, wherein the step of introducing a reactant comprises introducing a substantially pure silane into the at least one relatively low intensity plasma region.

10. The method as claimed in claim 1, further comprising the step of:
evacuating exhaust from the deposition chamber.

11. The method as claimed in claim 10, wherein the step of evacuating exhaust from the deposition chamber comprises evacuating exhaust through at least one of the plurality of rod electrodes.

12. The method as claimed in claim 10 wherein the steps of introducing a reactant and evacuating exhaust comprises introducing the reactant including film layer material into the at least one region of relatively low intensity plasma region and evacuating exhaust through adjacent rod electrodes.

13. The method as claimed in claim 10, further comprising the steps of:
measuring the amount of film layer material in the exhaust; and
adjusting a reactant input rate in response to the measured amount of film layer material in the exhaust.

14. The method as claimed in claim 13, wherein the step of adjusting the reactant input rate comprises adjusting the reactant input rate in response to the measured amount of film layer material in the exhaust while continuing to introduce the reactant.

15. The method as claimed in claim 10, further comprising the steps of:
measuring the pressure within the deposition chamber; and
adjusting the exhaust rate in response to the measured pressure within the deposition chamber while continuing to introduce the reactant.

16. The method as claimed in claim 1, wherein the at least one substrate comprises a first and second substrate.

17. The method as claimed in claim 16, further comprising the step of:
positioning the first and second substrates such that the at least one plasma region having a relatively low intensity is between each of the first and second substrates and the at least one plasma region having a relatively high intensity.

18. The method as claimed in claim 16, further comprising the step of:
positioning the first and second substrates on opposite sides of the plasma region having a relatively high intensity.

19. A method of forming a film on at least one substrate inside a deposition chamber, comprising the steps of:
generating a plasma within a deposition chamber with at least one region of relatively high intensity between a plurality of rod electrodes and away from the at least one substrate and at least one region of relatively low intensity plasma adjacent to the at least one substrate by driving adjacent rod electrodes out of phase from one another;
introducing a reactant including film layer material into the at least one relatively low intensity plasma region adjacent to the at least one substrate through at least one of the plurality of rod electrodes having internal lumens and apertures that connect the internal lumens to the deposition chamber, wherein the apertures are oriented toward the at least one substrate and away from the plurality of rod electrodes; and
depositing the film layer material onto the at least one substrate.

20. The method as claimed in claim 19, wherein RF power is supplied to each end of the adjacent rod electrodes.

21. The method as claimed in claim 19, wherein the adjacent rod electrodes have a parallel inductor attached to each longitudinal end.

22. The method as claimed in claim 19, further comprising the steps of:
evacuating exhaust from the deposition chamber;
measuring the amount of film layer material in the exhaust; and
adjusting the reactant input rate in response to the measured amount of film layer material in the exhaust.

23. The method as claimed in claim 22 wherein the step of evacuating exhaust from the deposition chamber comprises evacuating the exhaust through at least one of the plurality of rod electrodes.

24. The method as claimed in claim 23 wherein the steps of introducing a reactant and evacuating exhaust comprise introducing the reactant including film layer material into the at least one region of relatively low intensity plasma region and evacuating exhaust through adjacent rod electrodes.

25. The method as claimed in claim 22, further comprising the steps of
measuring the pressure within the deposition chamber; and
adjusting the exhaust rate in response to the measured pressure within the deposition chamber while continuing to introduce the reactant.

26. The method as claimed in claim 21 wherein the adjacent rod electrodes are driven at both longitudinal ends.

27. The method as claimed in claim 19 wherein the adjacent rod electrodes are driven by a power supply operably connected to the plurality of rod electrodes and wherein RF power is supplied in the 27-81 MHz excitation frequency range.
